(19) United States
(12) Patent Application Publication
(10) Pub. No.: US 2010/0117174 A1
(43) Pub. Date: May 13, 2010

(54) METHOD OF MANUFACTURING IMAGE SENSOR

(76) Inventor: Chung-Kyung Jung, Anyang-si (KR)

Correspondence Address: SHERR & VAUGHN, PLLC, 620 HERNDON PARKWAY, SUITE 320, HERNDON, VA, 20170, US

(21) Appl. No.: 12/613,789

(22) Filed: Nov. 6, 2009

(30) Foreign Application Priority Data
Nov. 11, 2008 (KR) 10-2008-0111441

(51) Int. Cl. H01L 31/02; H01L 21/768

(52) U.S. Cl. 257/431; 438/98; 438/653; 257/751; 257/E31.111; 257/E21.584

(57) ABSTRACT

A method of manufacturing an image sensor and devices thereof. A method of manufacturing an image sensor may include forming an interlayer dielectric layer, which may include a metal line, on and/or over a semiconductor substrate. A method of manufacturing an image sensor may include forming an image sensing part, including a stacked structure having a first doped layer and/or a second doped layer, on and/or over a interlayer dielectric layer. A method of manufacturing an image sensor may include forming a via hole, which may expose a metal line by perforating a image sensing part and/or a interlayer dielectric layer. A method of manufacturing an image sensor may include performing a cleaning process. An undercut may be formed on and/or over a image sensing part when a via hole is formed, and/or a native oxide layer may be substantially removed from a undercut through a cleaning process.

The present application claims priority under 35 U.S.C. 119 to Korean Patent Application No. 10-2008-0111441 (filed on Nov. 11, 2008) which is hereby incorporated by reference in its entirety.

### BACKGROUND

Embodiments relate to electric devices and methods thereof. Some embodiments relate to a method of manufacturing an image sensor.

Image sensors may include semiconductor devices which may convert an optical image into an electrical signal. Image sensors may be classified as a charge coupled device (CCD) and/or a CMOS image sensor (CIS). A CIS may have a structure in which a photodiode region may receive a light signal to convert a light signal into an electric signal, and which may be horizontally arranged with a transistor region to process an electric signal. A horizontal image sensor may have a structure in which a photodiode region and a transistor region are horizontally provided on and/or over a semiconductor substrate. A horizontal image sensor may have a limitation in expanding a light sensitivity region, for example a fill factor, within a restricted area.

To address the above described problems, a photodiode may be deposited using amorphous silicon (Si). Also, a readout circuitry may be formed on and/or over a Si-substrate through a wafer-to-wafer bonding scheme, and/or a photodiode may be formed on and/or over a readout circuitry, which may relate to a three-dimensional image sensor. A photodiode may be connected with a readout circuitry through a metal line.

During an etch process to divide photodiodes according to unit pixels, a lateral side of a photodiode may be further etched such that a natural oxide layer may be formed at an etched portion of a photodiode since, for example, a photodiode may include a substantially different than that of an interlayer dielectric layer. A natural oxide layer may maximize resistance of a device, and/or may minimize the relative sensitivity of a device, for example of an image sensor.

Accordingly, there is a need for a method of manufacturing an image sensor and an image sensor that may substantially minimize formation of a natural oxide layer, and/or which may maximize operation of a device.

### SUMMARY

Embodiments relate to a method of manufacturing an image sensor. According to embodiments, a method of manufacturing an image sensor may include forming an interlayer dielectric layer, which may include a metal line, on and/or over a semiconductor substrate. In embodiments, a method of manufacturing an image sensor may include forming an image sensing part, which may include a stacked structure of a first doped layer and/or a second doped layer, on and/or over a interlayer dielectric layer.

According to embodiments, a method of manufacturing an image sensor may include forming a via hole to expose a metal line by perforating a image sensing part and/or a interlayer dielectric layer. In embodiments, a method of manufacturing an image sensor may include performing a cleaning process with respect to a semiconductor substrate having a via hole. In embodiments, an undercut may be formed on and/or over a image sensing part when a via hole is formed. In embodiments, a method of manufacturing an image sensor may include removing a native oxide layer from an undercut through a cleaning process.

### DRAWINGS

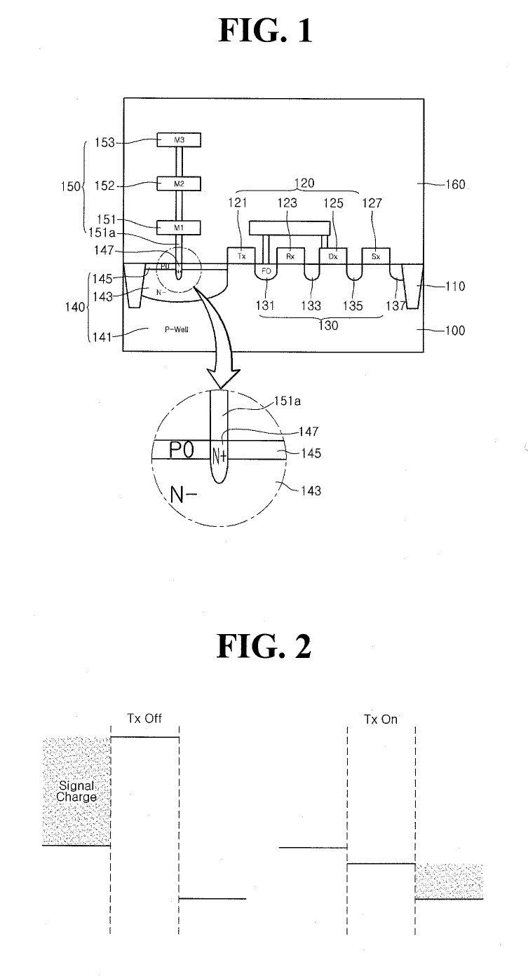

Example FIG. 1 to FIG. 9 are sectional views illustrating a manufacturing process of an image sensor in accordance with embodiments.

### DESCRIPTION

Embodiments relate to a method of manufacturing an image sensor. Embodiments are not limited to a CMOS image sensor, but may be applicable for example to substantially all image sensors, such as a CCD image sensor, which may require a photodiode. Referring to example FIG. 1 to FIG. 9, a method of manufacturing an image sensor in accordance with embodiments is illustrated.

Referring to FIG. 1, metal line 150 and/or interlayer dielectric layer 160 may be formed on and/or over a semiconductor substrate 100 which may include readout circuitry 120. According to embodiments, semiconductor substrate 100 may include a single-Si-substrate and/or a poly-Si-substrate. In embodiments, semiconductor substrate 100 may include a substrate doped with P-type impurities and/or N-type impurities.

According to embodiments, an isolation layer 110 may be formed on and/or over semiconductor substrate 100 to define an active region. In embodiments, readout circuitry 120 may include transistors and may be formed on and/or over an active region. In embodiments, readout circuitry 120 may include transfer transistor (Tx) 121, reset transistor (Rx) 123, drive transistor (Dx) 125 and/or select transistor (Sx) 127. In embodiments, ion implantation region 130 may include floating diffusion (FD) region 131. In embodiments, source/drain regions 133, 135, and/or 137 may be formed for each transistor. In embodiments, readout circuitry 120 may be applicable to a 3Tr structure and/or a 5Tr structure.

According to embodiments, electric junction region 140 may be formed on and/or over semiconductor substrate 100 when readout circuitry 120 is formed on and/or over semiconductor substrate 100. In embodiments, a first conductive type connection region 147 may be formed on and/or over electric junction region 140 such that first conductive type connection region 147 may be connected to metal line 150.

According to embodiments, electric junction region 140 may be a PN junction region, but embodiments are not limited thereto. In embodiments, electric junction region 140 may include second conductive type well 141, may include first conductive type ion implantation layer 143 which may be formed on and/or over a second conductive type epitaxial layer, and/or may include second conductive type ion implantation layer 145 which may be formed on and/or over first conductive type ion implantation layer 143. In embodiments, PN junction region 140 may be a P0 145/N− 143/P− 141 junction region, but embodiments are not limited thereto. In embodiments, first substrate 100 may be conducted with a second conductive type, but embodiments are not limited thereto.

According to embodiments, a device may be designed to have a potential difference between a source and a drain of both terminals of Tx 121, such that substantially fully-dumping of photo charges may be achieved. In embodiments, photo charges generated from a photodiode may be dumped into FD region 131, such that relative sensitivity of an output image may be maximized. In embodiments, electric junction region 140 may be formed on and/or over first substrate 100 formed including, readout circuitry 120 to enable a potential difference between a source and a drain of both terminals of Tx 121, such that substantially fully-dumping of photo charges may be achieved.

Embodiments relate dumping of photo charges. Referring to FIG. 1 and FIG. 2, a dumping structure is illustrated. According to embodiments, in contrast to FD node 131 having an N+ junction, a P0/N−/P− junction of electric junction region 140 may deliver a portion of applied voltage and may be pinched off at a predetermined voltage. In embodiments, a voltage for pinch-off may relate to a pinning voltage. In embodiments, a pinning voltage may depend on a doping concentration of P0 layer 145 and/or N− layer 143.

According to embodiments, electrons may be generated from a photodiode and may move into P0/N−/P− junction region 140. In embodiments, electrons may be delivered to FD node 131 when Tx 121 is turned on such that electrons may be converted into voltage. In embodiments, since the maximum voltage of P0/N−/P− junction region 140 may become pinning voltage and/or the maximum voltage of FD node 131 may be Vdd-Rx Vth, electrons generated from a photodiode positioned above a chip may be substantially fully dumped into FD node 131 substantially without charge sharing due to a potential difference between both terminals of Tx 121.

According to embodiment, a P0/N−/P-well junction may be formed on and/or over semiconductor substrate 100, for example a Si substrate, instead of a N+/P-well junction. In embodiments, since positive voltage may be applied to N-layer 143 and ground voltage may be applied to P0 145 and/or P-well 141 in a P0/N−/P-well junction at 4-Tr APS reset operation, a P0/N−/P-well double junction structure may be pinched off over a predetermined voltage similar to a BJT structure. In embodiments, voltage may relate to a pinning voltage. In embodiments, potential difference may occur between a source/drain of both terminals, for example a source and a drain, of Tx 121, such that photo charges may be substantially fully dumped into FD 131 from an N-well through Tx 121 at an on/off operation of Tx 121. In embodiments, charge sharing may be minimized. In embodiments, and unlike when a photodiode is connected with an N+ junction region, degradation of saturation and/or sensitivity may be minimized

According to embodiments, first conductive type connection region 147 may be formed between a photodiode and readout circuitry 120. In embodiments, a relatively smooth moving path of photo charges may be formed. In embodiments, a dark current source may be minimized. In embodiments, degradation of saturation and/or sensitivity may be minimized.

According to embodiments, an N+ doping region may be formed on and/or over a surface of P0/N−/P− junction region 140 as first conductive type connection region 147 for ohmic contact. In embodiments, N+ region 147 may contact N− region 143 through P0 region 145. In embodiments, a width of first conductive connection region 147 may be minimized to protect first conductive connection region 147 from becoming a substantial leakage source.

According to embodiments, a plug implant may be performed after metal contact 151a is etched, but embodiments are not limited thereto. In embodiments, first conductive connection region 147 may be formed using an ion implantation pattern as an ion implantation mask after forming an ion implantation pattern. In embodiments, only a contact forming portion may be locally doped with N+ impurities to facilitate a formation of ohmic contact while minimizing a dark signal instead of when an entire surface of a Tx source is doped with N+ impurities such that a dark signal may be maximized due to Si surface dangling bond.

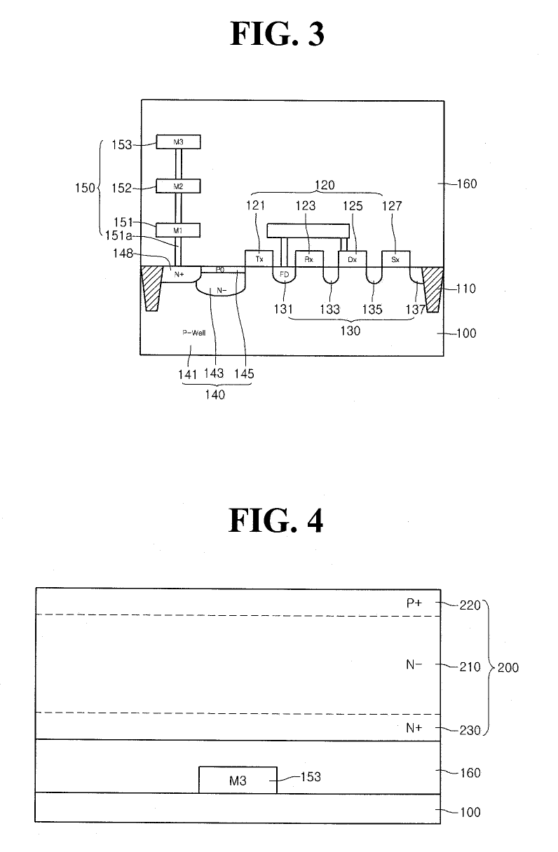

Referring to FIG. 3, a sectional view illustrates a structure of a readout circuitry in accordance with embodiments. According to embodiments, first conductive type connection region 148 may be formed at one side of electric junction region 140. In embodiments, N+ connection region 148 may be formed on and/or over P0/N−/P− junction region 140 for ohmic contact.

A process of forming N+ connection region 148 and/or M1C contact 151 a may become a leakage source. Since reverse bias voltage may be applied to P0/N−/P− junction region 140 upon operation, an electric field may be generated on and/or over a surface of a substrate. The crystal defect generated under an electric field during a process of forming a contact may become a leakage source. The electric field may be additionally generated by N+ /P0 junction regions 148 and 145 when the N+ connection region 148 is formed on and/or over a surface of the P0/N−/P− junction region 140, such that a leakage source may be further created.

According to embodiments, a layout is illustrated in which contact plug 151 a may be formed on and/or over an active region including N+ connection region 148 without being doped into a P0 layer, such that contact plug 151a may be connected to N− junction region 143. In embodiments, an electric field may not be generated on and/or over a surface of substrate 100, which may be a silicon substrate. In embodiments, a dark current may be minimized, for example in a three-dimensional integrated CIS.

Referring back to FIG. 1, interlayer dielectric layer 160 and/or metal line 150 may be formed on and/or over semiconductor substrate 100. According to embodiments, metal line 150 may include metal contact 151a, first metal M1 151, second metal M2 152 and/or third metal M3 153, but embodiments are not limited thereto. In embodiments, after a third metal has been formed, interlayer dielectric layer 160 may be formed through a planarization process after depositing an insulating layer to prevent third metal 153 from being exposed. In embodiments, a surface of interlayer dielectric layer 160 having a substantially uniform surface profile may be exposed on and/or over semiconductor substrate 100.

Referring to FIG. 4, image sensing part 200 may be formed on and/or over interlayer dielectric layer 160. According to embodiments, image sensing part 200 may have a photodiode structure of a PN junction including first doped layer (N− layer) 210 and/or second doped layer (P+ layer) 220. In embodiments, image sensing part 200 may include ohmic contact layer (N+ layer) 230, which may be under first doped layer 210.

According to embodiments, third metal 153 of metal line 150 and/or interlayer dielectric layer 160 illustrated in FIG. 4 may represent a portion of metal line 150 and/or a portion interlayer dielectric layer 160 illustrated in FIG. 1. In embodiments, readout circuitry 120 and a portion of metal line 150 may be omitted for the purpose of explanation. In embodiments, image sensing part 200 may be formed in a stacked structure including first doped layer 210 and second doped layer 220, for example formed by sequentially implanting N-type impurities (N−) and P-type impurities (P+) on and/or over a crystalline P-type carrier substrate In embodiments, high-concentration N-type impurities (N+) may be implanted on and/or over a lower portion of first doped layer 210 to form ohmic contact layer 230. In embodiments, ohmic contact layer 230 may reduce contact resistance between image sensing part 200 and metal line 150. In embodiments, first doped layer 210 may have an area wider than that of second doped layer 220. In embodiments, a depletion region may be extended. In embodiments, generation of photo charges may be maximized.

According to embodiments, semiconductor substrate 100 may be bonded with a carrier substrate, for example after ohmic contact layer 230 of a carrier substrate has been positioned on and/or over interlayer dielectric layer 160. In embodiments, a carrier substrate having a hydrogen layer may be removed through a cleaving process such that image sensing part 200, which may be bonded with interlayer dielectric layer 160, may be exposed. In embodiments, a surface of second doped layer 220 may be exposed. In embodiments, image sensing part 200 may have a height between approximately 1.0 μm and 1.5 μm. In embodiments, semiconductor substrate 100 having readout circuitry 120 may be bonded with image sensing part 120 through a wafer-to-wafer bonding scheme, such that defects may be minimized.

According to embodiments, image sensing part 200 may be formed above readout circuitry 120 to maximize a fill factor. In embodiments, since image sensing part 200 may be bonded with interlayer dielectric layer 160 having a substantially uniform surface profile, a physical bonding strength between photodiode 200 and interlayer dielectric layer 260 may be maximized. In embodiments, even though image sensing part 200 may include a PN junction structure, image sensing part 200 may include a PIN junction structure.

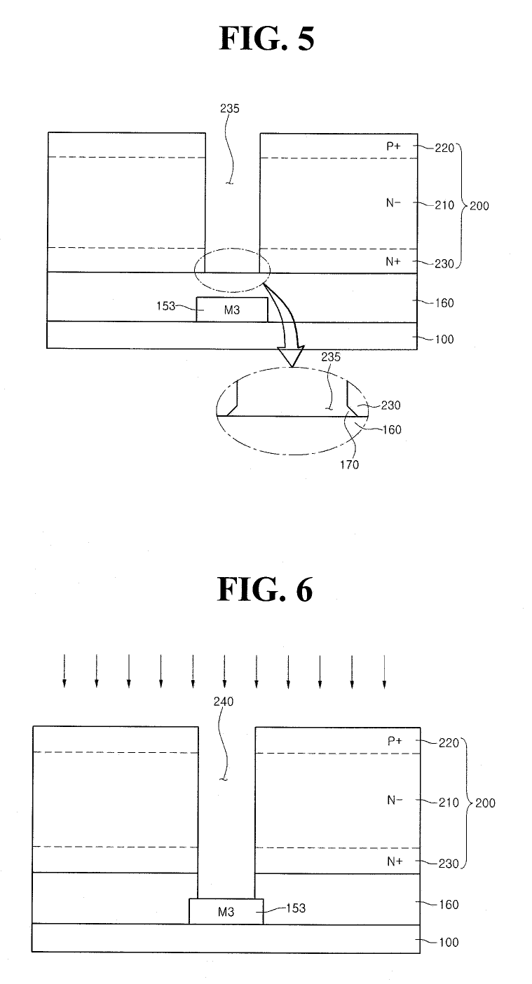

Referring to FIG. 5, first via hole 235 passing through image sensing part 200 and/or interlayer dielectric layer 160 may be formed. In embodiments, first via hole 235 may be formed by selectively etching image sensing part 200 after forming a hard mask and a photoresist pattern on and/or over image sensing part 200. In embodiments, first via hole 235 may be formed through a first etch process.

According to embodiments, since image sensing part 200 may include a material substantially different from that of interlayer dielectric layer 160, an undercut 170 may be formed due to additional etch of a lateral side of image sensing part 200 instead of interlayer dielectric layer 160. In embodiments, a native oxide layer may be formed at undercut 170 to block current flow by maximizing resistance between image sensing part 200 and interlayer dielectric layer 160 when a via hole may be filled.

Referring to FIG. 6, second via hole 240 passing through interlayer dielectric layer 160 may be formed. In embodiments, second via hole 240 may expose a surface of third metal 153 which may be provided on and/or over interlayer dielectric layer 160. In embodiments, second via hole 240 may be formed by selectively etching image sensing part 200 and/or interlayer dielectric layer 160 after forming a hard mask and a photoresist pattern on and/or over image sensing part 200. In embodiments, an opening of a hard mask and a photoresist pattern may expose a surface of image sensing part 200 corresponding to third metal 153. In embodiments, a photoresist pattern may be removed through an ashing process, and a hard mask may remain on and/or over image sensing part 200. In embodiments, a hard mask may be removed. In embodiments, second via hole 240 may be formed through a second etch process.

According to embodiments, a cleaning process may be performed with respect to second via hole 240 to substantially remove a native oxide layer. In embodiments, a cleaning process may be performed using chemicals such as diluted hydrogen fluoride (DHF) and/or buffered hydrogen fluoride (BHF). In embodiments, a loss of interlayer dielectric layer 160 may be minimized through a cleaning process. In embodiments, a cleaning process may be performed to the extent that a native oxide layer can be removed by approximately 10 Å to 50 Å.

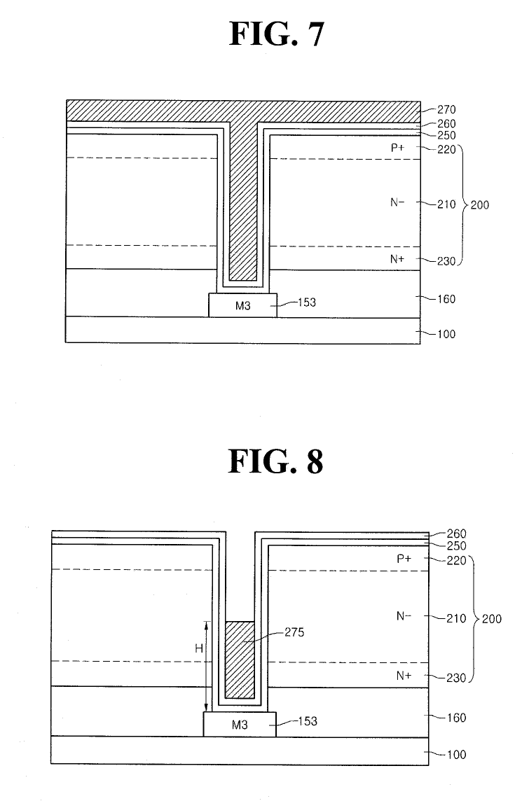

Referring to FIG. 7, first and/or second barrier layers 250 and 260, respectively, and metal layer 270 may be formed on and/or over image sensing part 200 having second via hole 240. In embodiments, first and/or second barrier layers 250 and 260, respectively, may include titanium (Ti) and/or titanium nitride (TiN), respectively. In embodiments, metal layer 270 may include tungsten (W), copper (Cu) and/or aluminum (Al). In embodiments, metal layer 270 may include (W).

According to embodiments, first and/or second barrier layers 250 and 260, respectively, and/or metal layer 270 may be formed within approximately two hours after a cleaning process has been performed. In embodiments, a native oxide layer may be substantially prevented from being formed at undercut 170. In embodiments, first and/or second barrier layers 250 and 260, respectively, may be formed at undercut 170.

According to embodiments, first and/or second barrier layers 250 and 260, respectively, may substantially prevent third metal 153, which may be exposed by second via hole 240, from being oxidized and/or may protect interlayer dielectric layer 160. In embodiments, first and/or second barrier layers 250 and 260, respectively, may be formed with a relatively thin thickness along a step difference of image sensing part 200 and/or second via hole 240. In embodiments, metal layer 270 may be formed by depositing metal such that the metal is substantially gap-filled on and/or over second via hole 240 having first and/or second barrier layers 250 and 260, respectively.

Referring to FIG. 8, contact plug 275 may be formed inside second via hole 240 by etching metal layer 270 through a primary etch process. According to embodiments, a primary etch process may relate to an etch back process for metal layer 270. In embodiments, a primary etch process may selectively remove only tungsten (W). In embodiments, contact plug 275 may be formed through an etch process employing SFx gas, where X may be between approximately 1 and 6, and Ar gas may be an etch gas. In embodiments, SFx gas may deform a surface of a Ti layer and/or a TiN layer instead of etching a Ti layer and/or a TiN layer. In embodiments, a deformed portion may be a defect source due to plasma damage, such that an additional process to remove first and second barrier layers 250 and 260, respectively, may be performed.

According to embodiments, contact plug 275 formed through a primary etch process may have a height corresponding to a height of first doped layer 210. In embodiments, contact plug 275 may expose second barrier layer 260 of second via hole 240 corresponding to second doped layer 220. In embodiments, as contact plug 275 is formed, a predetermined portion of second barrier layer 260 may be exposed. In embodiments, a predetermined portion may correspond to second doped layer 220 and/or an upper portion of first doped layer 210 contacting second doped layer 220 on the basis of a side wall of second via hole 240. In embodiments, contact plug 275 may have a first height H from third metal 153.

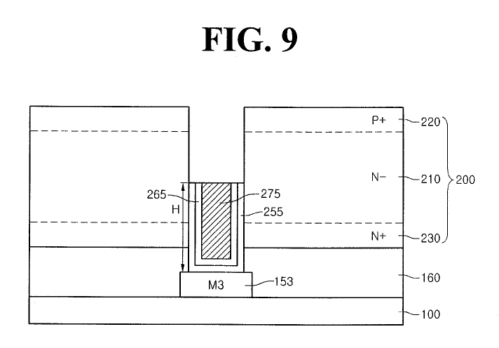

Referring to FIG. 9, second barrier pattern 255 may be formed by performing a secondary etch process for second barrier layer 260. In embodiments, first barrier pattern 265 may be formed by performing a tertiary etch process for first barrier layer 250 to form first barrier pattern 250. In embodiments, first barrier pattern 265, second barrier pattern 255 and/or contact plug 275 may have substantially the same first height (H). In embodiments, a sidewall of second via hole 240 may be exposed.

According to embodiments, first and/or second barrier patterns 265 and 255, respectively, and/or contact plug 275 may be electrically connected to first doped layer 210 of second via hole 240 and/or third metal 153. In embodiments, photo charges generated from image sensing part 200 may be delivered to readout circuitry 120. In embodiments, since first and/or second barrier patterns 265 and 255, respectively, and/or contact plug 275 may be electrically connected to first doped layer 210 of second via hole 240, first and/or second doped layers 210 and 220, respectively, may be insulated from each other. In embodiments, erroneous operation of a may be minimized.

According to embodiments, an upper electrode, a color filter and/or a micro-lens may be formed on and/or over image sensing part 200. In embodiments, a method of manufacturing an image sensor may enable a native oxide layer to be formed at an undercut, which may be formed in an etch process to form a via hole in an image sensing part, and/or which may be substantially removed. In embodiments, reliability of a device may be maximized.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming an interlayer dielectric layer including a metal line over a semiconductor substrate;
forming an image sensing part including a stacked structure having a first doped layer and a second doped layer over said interlayer dielectric layer;
forming a via hole to expose said metal line by perforating said image sensing part and said interlayer dielectric layer; and
performing a cleaning process with respect to said semiconductor substrate having said via hole,
wherein an undercut is formed in said image sensing part when said via hole is formed, and a native oxide layer is substantially removed from the undercut through the cleaning process.

2. The method of claim 1, comprising forming a first barrier pattern, a second barrier pattern and a contact plug in said via hole after said cleaning process.

3. The method of claim 2, wherein said first barrier pattern, said second barrier pattern and said contact plug are formed in said via hole within approximately two hours after said cleaning process has been performed.

4. The method of claim 2, wherein forming said first barrier pattern, said second barrier pattern and said contact plug comprises:
forming a first barrier layer and a second barrier layer over a sidewall and a bottom surface of said via hole;
forming a contact plug in said via hole having a first height corresponding to said first doped layer to expose said second barrier layer corresponding to said second doped layer;
forming said second barrier pattern having a height substantially the same height as said contact plug by performing a first etch process with respect to said second barrier layer; and
forming said first barrier pattern by performing a second etch process with respect to said first barrier layer to expose said second doped layer inside said via hole.

5. The method of claim 4, wherein forming said contact plug comprises:
forming a metal layer substantially filling said via hole having said first barrier layer and second barrier layer; and
selectively removing said metal layer by performing an etch back process with respect to said metal layer such that said metal layer includes a first height corresponding to said first doped layer.

6. The method of claim 4, wherein said first barrier layer comprises titanium.

7. The method of claim 4, wherein said second barrier layer comprises titanium nitride.

8. The method of claim 1, wherein said cleaning process comprises using at least one of diluted hydrogen fluoride and buffered hydrogen fluoride.

9. The method of claim 1, wherein said native oxide layer having a thickness between approximately 10 Å and 50 Å is substantially removed through said cleaning process.

10. The method of claim 1, wherein said contact plug comprises tungsten.

11. An apparatus comprising:
an interlayer dielectric layer including a metal line over a semiconductor substrate;
an image sensing part including a stacked structure having a first doped layer and a second doped layer over said interlayer dielectric layer;
a via hole exposing said metal line by perforating said image sensing part and said interlayer dielectric layer;
an undercut formed in said image sensing part when said via hole is formed substantially without a native oxide layer substantially removed through a cleaning process.

12. The apparatus of claim 11, comprising a first barrier pattern, a second barrier pattern and a contact plug formed in said via hole after said cleaning process.

13. The apparatus of claim 12, wherein said first barrier pattern, said second barrier pattern and said contact plug are formed in said via hole within approximately two hours after said cleaning process has been performed.

14. The apparatus of claim 12, comprising:
a first barrier layer and a second barrier layer over a sidewall and a bottom surface of said via hole;
a contact plug formed in said via hole having a first height corresponding to said first doped layer to expose said second barrier layer corresponding to said second doped layer;
wherein said second barrier pattern is formed having a height substantially the same height as said contact plug by performing a first etch process with respect to said second barrier layer; and
wherein said first barrier pattern is formed by performing a second etch process with respect to said first barrier layer to expose said second doped layer inside said via hole.

15. The apparatus of claim 14, comprising:
selectively removing a metal layer formed substantially filling said via hole having said first barrier layer and second barrier layer by performing an etch back process with respect to said metal layer such that said metal layer includes a first height corresponding to said first doped layer.

16. The apparatus of claim 14, wherein said first barrier layer comprises titanium.

17. The apparatus of claim 14, wherein said second barrier layer comprises titanium nitride.

18. The apparatus of claim 11, wherein said cleaning process comprises using at least one of diluted hydrogen fluoride and buffered hydrogen fluoride.

19. The apparatus of claim 11, wherein said native oxide layer having a thickness between approximately 10 Å and 50 Å is substantially removed through said cleaning process.

20. The apparatus of claim 11, wherein said contact plug comprises tungsten.
